(19) United States
(12) Patent Application Publication
(10) Pub. No.: US 2016/0126144 A1
(43) Pub. Date: May 5, 2016

(54) METHODS OF FORMING A METAL-INSULATOR-SEMICONDUCTOR (MIS) STRUCTURE AND A DUAL CONTACT DEVICE

(71) Applicant: QUALCOMM Incorporated, San Diego, CA (US)

(72) Inventors: Jeffrey Junhao Xu, San Diego, CA (US); Kern Rim, San Diego, CA (US); John Jianhong Zhu, San Diego, CA (US); Stanley Seungchul Song, San Diego, CA (US); Choh Fei Yeap, San Diego, CA (US)

(21) Appl. No.: 14/991,882

(22) Filed: Jan. 8, 2016

Related U.S. Application Data
(62) Division of application No. 14/284,958, filed on May 22, 2014.
(60) Provisional application No. 61/955,695, filed on Mar. 19, 2014.

(51) Int. Cl. H01L 21/8238; H01L 21/285; H01L 21/324; H01L 29/66

(52) U.S. Cl. CPC H01L 21/823814; H01L 29/66477; H01L 21/28556; H01L 21/324

(57) ABSTRACT

A method includes forming a first metal layer on source/drain regions of an n-type metal-oxide-semiconductor (NMOS) device and on source/drain regions of a p-type MOS (PMOS) device by chemical vapor deposition (CVD) or non-energetic physical vapor deposition (PVD). The method further includes selectively performing a rapid thermal anneal (RTA) process on the first metal layer after forming the first metal layer.

### I. CROSS-REFERENCE TO RELATED APPLICATIONS

The present application claims priority from and is a divisional application of U.S. Non-Provisional patent application Ser. No. 14/284,958, filed May 22, 2014 and entitled “METHODS OF FORMING A METAL-INSULATOR-SEMICONDUCTOR (MIS) STRUCTURE AND A DUAL CONTACT DEVICE,” and claims priority to U.S. Provisional Patent Application No. 61/955,695, filed Mar. 19, 2014, entitled “METHODS OF FORMING A METAL-INSULATOR-SEMICONDUCTOR (MIS) STRUCTURE AND A DUAL CONTACT DEVICE,” the contents of each of which are incorporated herein by reference in their entirety.

### II. FIELD

The present disclosure is generally related to methods of forming semiconductor devices.

### III. DESCRIPTION OF RELATED ART

Performance of metal-oxide-semiconductor (MOS) devices can be affected by various factors, including channel length, strain, and external resistance. A contributor to external resistance is contact resistance between source/drain regions and metal layers. The contact resistance (e.g., Schottky barrier height) may be larger in n-type devices than in p-type devices.

To reduce contact resistance, metal-insulator-semiconductor (MIS) structures have been developed to form contacts between the source/drain regions and the metal layers. For example, when a titanium dioxide (TiO₂) layer is deposited between a source/drain region and a metal layer, the contact resistance may be reduced (e.g. in terms of in Schottky barrier height). A dual-layer structure has been proposed in which a titanium (Ti) layer is deposited on the TiO₂ layer. The dual-layer structure is produced using two separate deposition techniques. For example, the TiO₂ layer is deposited by an atomic layer deposition (ALD) technique, and the Ti layer is deposited by a physical vapor deposition (PVD) technique. When both ALD and PVD are used, a first region may be masked when PVD is applied to a second region, and the second region may be masked when ALD is applied to the first region. Using multiple masks during fabrication results in increased costs.

### IV. SUMMARY

This disclosure presents particular embodiments of a method of forming a dual contact metal-insulator-semiconductor (MIS) structure. For example, the MIS structure may be a tungsten (W)/titanium (Ti)/titanium dioxide (TiO₂₋ₓ)/silicon (Si) structure. An optional titanium nitride (TiN) barrier layer between W layer and the Ti layer may be used when the W layer contains fluorine (F). The method may reduce a number of mask processes used in forming the dual contact MIS structure.

In a particular embodiment, a method includes depositing a first metal layer on a source/drain region of an n-type metal-oxide-semiconductor (NMOS) device using a chemical vapor deposition (CVD) or non-energetic physical vapor deposition (PVD) process. The source/drain region may include silicon (Si). The first metal layer may include Ti. Prior to depositing the first metal layer, a surface of the source/drain region may be exposed to oxygen (e.g., air or another oxygenated environment) such that an oxide layer is formed on the surface of the source/drain region. For example, when the source/drain region includes Si, a layer including silicon dioxide (SiO₂) may be formed on the surface of the source/drain region. The method also includes selectively performing a rapid thermal anneal (RTA) process on the first metal layer. As a result of the RTA process, the first metal in the first metal layer may deplete oxygen in the oxide layer on the surface of the source/drain region. Thus, an oxide layer of the first metal may be formed between the first metal layer and the source/drain region. For example, when the source/drain region includes Si and the first metal layer includes Ti, after performing the RTA process, a layer including TiO₂₋ₓ may be formed between the Ti layer and the source/drain region. Alternatively, the RTA process may be not be performed when the temperature and/or energy of the CVD or PVD process used to form the first metal layer is high enough to cause the formation of TiO₂₋ₓ. The method may further include forming a second metal layer on the first metal layer. For example, the second metal layer may include W. An optional TiN barrier layer between the W layer and the Ti layer may be used when the W layer contains F.

In another particular embodiment, a method includes depositing a first metal layer on a source/drain region of an NMOS device and on a source/drain region of a p-type metal-oxide-semiconductor (PMOS) device using a CVD process or non-energetic physical vapor deposition (PVD). For example, the source/drain region of the NMOS device may include silicon (Si). The source/drain region of the PMOS device may include silicon germanium (SiGe) or germanium (Ge). The first metal layer may include Ti. Prior to depositing the first metal layer, surfaces of the source/drain regions may be exposed to oxygen such that oxide layers are formed on the surfaces of the source/drain regions. For example, when the source/drain region of the NMOS device includes Si, a layer including SiO₂ is formed on the surface of the source/drain region. When the source/drain region of the PMOS device includes Ge or SiGe, a layer including germanium oxide (GeO₂) or silicon germanium oxide (SiGeO₂) layer may be formed on the source/drain region. A thermal treatment process may be applied on the surface of the source/drain region of the PMOS device to remove the GeO₂ or SiGeO₂ layer. The method also includes selectively performing an RTA process on the first metal layer. As a result of the RTA process, an oxide layer of the first metal may be formed between the first metal layer and the source/drain region in the NMOS device. Additionally, or in the alternative, the first metal layer may be transformed into a compound layer of the first metal in the PMOS device. For example, when the first metal layer includes Ti, a layer including TiO₂₋ₓ may be formed between the Ti layer and the source/drain region in the NMOS device, and the Ti layer may be transformed into a layer including titanium silicon germanium (TiSiGe) or titanium germanium (TiGe) on the source/drain regions of the PMOS device. The method may further include depositing a second metal layer on the first metal layer in the NMOS device and on the compound layer of the first metal in the PMOS device. For example, the second metal layer may include W.

One particular advantage provided by at least one of the disclosed embodiments is an ability to form an MIS structure (corresponding to an NMOS device) and a PMOS device (i.e., two different types of contacts) simultaneously (e.g., using a single process). Thus, a number of mask processes may be reduced as compared to a conventional method of forming the MIS structure and the PMOS device.

Another particular advantage provided by at least one of the disclosed embodiments is that the method enables forming an MIS structure that has a lower contact resistance than an MIS structure formed by a conventional method. Thus, performance of an NMOS device may be further improved.

Other aspects, advantages, and features of the present disclosure will become apparent after review of the entire application, including the following sections: Brief Description of the Drawings, Detailed Description, and the Claims.

### V. BRIEF DESCRIPTION OF THE DRAWINGS

FIG. 1 is a diagram of a particular embodiment of a metal-insulator-semiconductor (MIS) structure in an n-type metal-oxide-semiconductor (NMOS) device;

FIG. 2 is a diagram of a particular embodiment of a first stage of forming an MIS structure;

FIG. 3 is a diagram of a particular embodiment of a second stage of forming an MIS structure;

FIG. 4 is a diagram of a particular embodiment of a third stage of forming an MIS structure;

FIG. 5 is a diagram of a particular embodiment of a dual contact device that includes an NMOS device with an MIS structure and a PMOS device;

FIG. 6 is a diagram of a particular embodiment of a first stage of forming a dual contact device;

FIG. 7 is a diagram of a particular embodiment of a second stage of forming a dual contact device;

FIG. 8 is a diagram of a particular embodiment of a third stage of forming a dual contact device;

FIG. 9 is a diagram of a particular embodiment of a fourth stage of forming a dual contact device;

FIG. 10 is a flow chart of a particular embodiment of a method of forming an MIS structure in an NMOS device;

FIG. 11 is a flow chart of a particular embodiment of a method of forming a dual contact device that includes an NMOS device with an MIS structure and a PMOS device;

FIG. 12 is a block diagram of a particular illustrative embodiment of a wireless communication device that includes the MIS structure of FIG. 1, the dual contact device of FIG. 5, or both; and

FIG. 13 is a data flow diagram of a particular illustrative embodiment of a manufacturing process to fabricate a device including the MIS structure of FIG. 1, the dual contact device of FIG. 5, or both.

### VI. DETAILED DESCRIPTION

This disclosure relates generally to a method of forming a dual contact metal-insulator-semiconductor (MIS) structure in an n-type metal-oxide-semiconductor (NMOS) device. For example, the MIS structure may include a tungsten (W)-titanium (Ti)/titanium oxide (TiO₂₋ₓ)-silicon (Si) structure.

In a particular embodiment, a method of forming the MIS structure includes depositing a first metal layer (e.g., a Ti layer) on a source/drain region (e.g., a Si source/drain region) of an NMOS device by chemical vapor deposition (CVD) or non-energetic physical vapor deposition (PVD). Prior to depositing the first metal layer, the source/drain region may have an oxide surface layer (e.g., a silicon dioxide (SiO₂) layer). For example, the oxide surface layer may be formed as a result of a reaction between oxygen and the source/drain region. An RTA process may subsequently be performed on the first metal layer. As a result of the RTA process, a metal oxide layer (e.g., a TiO₂₋ₓ layer) may be formed between the first metal layer (i.e., the Ti layer) and the source/drain regions (i.e., the Si source/drain regions). Alternatively, if a temperature/energy of the CVD or PVD process is high enough to cause formation of the metal oxide layer, the RTA process may not be performed. A second metal layer (e.g., a W layer) may be deposited on the first metal layer (i.e., the Ti layer).

In another particular embodiment, a method of forming an NMOS device and a PMOS device includes depositing a first metal layer (e.g., a Ti layer) on a source/drain region (e.g., a Si source/drain region) of the NMOS device and on a source/drain region (e.g., a Germanium (Ge) or Silicon Germanium (SiGe) source/drain region) of the PMOS device using a CVD or non-energetic PVD process. Prior to depositing the first metal layer (i.e., the Ti layer), the source/drain region of the NMOS device may have an oxide surface layer (e.g., a SiO₂ layer). For example, the oxide surface layer may be formed as a result of a reaction between oxygen and the source/drain region. Likewise, the source/drain region (i.e., the Ge or SiGe source/drain region) of the PMOS device may have an oxide surface layer (e.g., a germanium oxide (GeO₂) or silicon germanium oxide (SiGeO₂) layer). A thermal treatment may be applied to remove the oxide layer on the source/drain region of the PMOS device while leaving the oxide layer on the source/drain region of the NMOS device in place. An RTA process may be subsequently performed on the first metal layer. As a result of the RTA process, a metal oxide layer (e.g., a TiO₂₋ₓ) may be formed between the first metal layer and the source/drain region of the NMOS device. The first metal layer of the PMOS device may be transformed into a different layer (e.g., a titanium silicon germanium layer (TiSiGe)). A second metal layer (e.g., a W layer) may be deposited on the first metal layer.

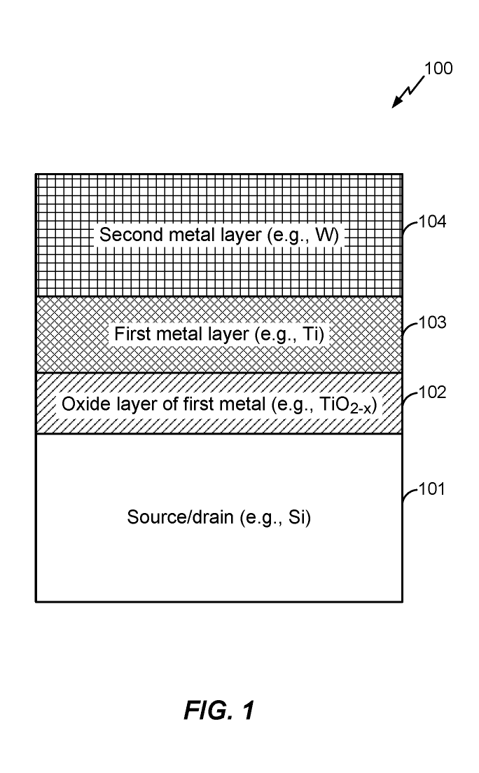

Referring to FIG. 1, a diagram of a particular embodiment of an MIS structure in an NMOS device is disclosed and generally designated 100. The MIS structure 100 may include a source/drain region 101, an oxide layer 102, a first metal layer 103, and a second metal layer 104. In an illustrative embodiment, the source/drain region 101 includes Si, the first metal layer 103 includes Ti, the oxide layer 102 includes TiO₂₋ₓ, and the second metal layer 104 includes W. It should be noted that the various materials described herein are for example only and not to be considered limiting. In alternate embodiments, other materials may be used to form NMOS and PMOS devices.

As shown in FIG. 1, the oxide layer 102 may be disposed on the source/drain region 101. The first metal layer 103 may be disposed on the oxide layer 102. The second metal layer 104 may be disposed on the first metal layer 103.

The source/drain region 101 may include one or more elements, compounds, or materials that enable a device to function as an NMOS device. For example, the source/drain region 101 may include Si. Prior to depositing another layer on the source/drain region 101, a surface of the source/drain region 101 may be reacted to form an oxide surface layer (not shown). For example, the source/drain region 101 may be reacted with oxygen to form the oxide surface layer. Thus, the oxide surface layer may include SiO₂.

The oxide layer 102 may be disposed on the source/drain region 101. The oxide layer 102 may have various thicknesses. For example, the oxide layer 102 may be approximately 10 angstrom in thickness. Oxide layers that are thinner than or thicker than approximately 10 angstrom may increase the contact resistance of the MIS structure.

The first metal layer 103 may be formed by depositing a first metal on the source/drain region 101 using chemical vapor deposition (CVD) or non-energetic physical vapor deposition (PVD). The first metal layer 103 may include any metal element, compound, or material that is capable of being deposited using the CVD or non-energetic PVD process and forming the oxide layer 102. For example, the first metal layer may include Ti. After depositing the first metal layer 103, an RTA process may be performed on the first metal layer 103. For example, the RTA process may be performed at a temperature of between 600 and 800° C. As a result of the RTA process, the oxide layer 102 may be formed between the source/drain region 101 and the first metal layer 103. For example, when the source/drain region 101 includes Si and the first metal layer includes Ti, the oxide layer 102 may include TiO₂₋ₓ. Alternatively, the RTA process may be skipped in response to determining that a temperature and/or energy of the CVD or non-energetic PVD process used to form the first metal layer 103 is high enough to cause formation of the oxide layer 102.

The second metal layer 104 may be formed by depositing a second metal on the first metal layer 103. The second metal layer 104 may include any metal element, compound, or material that is suitable for conducting signals between the source/drain region 101 and circuits. For example, the second metal layer 104 may include W. In a particular embodiment, when the W layer (e.g., the second metal layer 104) includes fluorine (F), a titanium nitride (TiN) barrier layer may be formed on a Ti layer (e.g., the first metal layer 103) prior to forming the W layer.

FIG. 1 thus illustrates an MIS structure 100 of an NMOS device. For example, the MIS structure may correspond to an NMOS device that is formed along with a PMOS device on a single substrate or wafer. As described above, and as described further below, the MIS structure 100 may be formed using a process that uses fewer masks that methods previously used to form the MIS structures. To illustrate, the NMOS device and the PMOS device may collectively represent a “dual contact” device that includes two different types of contacts. For example, the PMOS device may have a different type contact structure than the MIS structure of the NMOS device. As described further below, the NMOS device and the PMOS device may be formed on a single substrate or wafer using a common process that does not include masking the NMOS device during formation of the PMOS device, and vice versa. Thus, a total number of masks used during fabrication may be reduced, which may reduce fabrication costs.

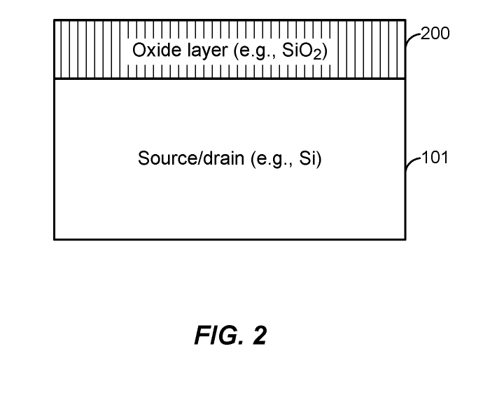

FIGS. 2-4 illustrate stages of a process of manufacturing an MIS structure, such as the MIS structure 100 of FIG. 1. Referring to FIG. 2, a diagram of a particular embodiment of a first stage of forming an MIS structure in an NMOS device is shown. In FIG. 2, an oxide surface layer 200 is formed on a source/drain region 101. The oxide surface layer 200 may be formed on the source/drain region 101 by reacting the source/drain region in an oxygenated environment (e.g., with air). When the source/drain region 101 includes Si, the oxide surface layer 200 may include SiO₂. In alternate embodiments, the source/drain region 101 may include a different material and the oxide surface layer 200 may include different oxide.

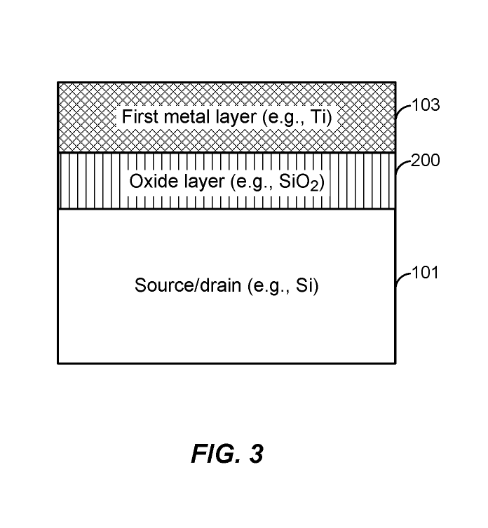

Referring to FIG. 3, a diagram of a particular embodiment of a second stage of forming an MIS structure in an NMOS device is shown. The second stage may follow the first stage of FIG. 2. In FIG. 3, a first metal layer 103 is formed on a source/drain region 101. The first metal layer 300 may be deposited (e.g., using a CVD or non-energetic PVD process). The first metal layer 103 may include any metal element, compound, or material that is capable of being deposited using the CVD or non-energetic PVD process and forming the oxide layer 102 of FIG. 1. For example, the first metal layer 103 may include Ti.

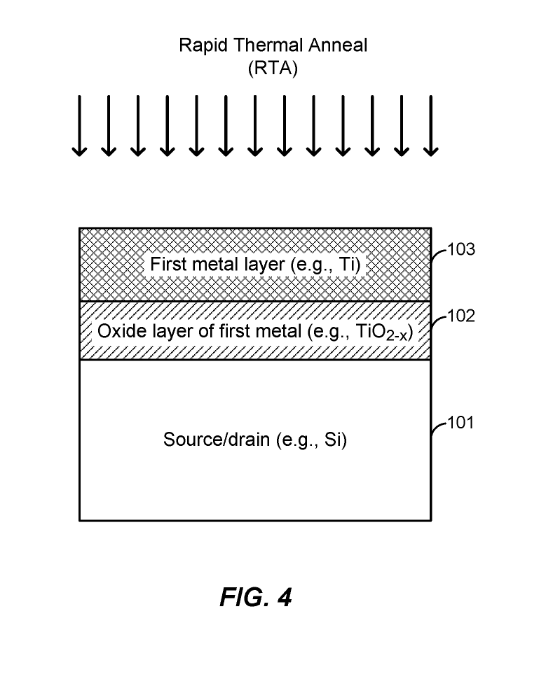

Referring to FIG. 4, a diagram of a particular embodiment of a third stage of forming an MIS structure in an NMOS device is shown. The third stage may follow the second stage of FIG. 3. In FIG. 4, an oxide layer 102 of the first metal is formed between the source/drain region 101 and the first metal layer 103. The oxide layer 102 may be formed using an RTA process. For example, the first metal layer 103 (e.g., a Ti layer) may be heated using the RTA process. The first metal in the first metal layer 103 may react with oxygen in the oxide layer on the source/drain region 101 (e.g., the oxide layer 200 of FIG. 2). As a result, the oxide layer 102 may be formed between the first metal layer 103 and the source/drain region 101. For example, when the first metal layer 103 includes Ti layer, the oxide layer 102 may include TiO₂₋ₓ. A thickness of the oxide layer 102 may be related to a magnitude of contact resistance between the source/drain region 101 and the second metal layer 104. For example, when the oxide layer 102 is approximately 10 angstrom in thickness, the MIS structure 100 may have a suitable contact resistance. In a particular embodiment, the thickness of the oxide layer 102 may be controlled by controlling how long the source/drain region 101 is reacted with oxygen, a thickness of the first metal layer 103, a temperature of the RTA process, a duration of the RTA process, or a combination thereof. It should be noted that although FIG. 4 illustrates an RTA process, in alternate embodiments the oxide layer 102 may be formed without an RTA process. For example, the RTA process may be skipped if a temperature/energy of the CVD or PVD process used to form the first metal layer 103 (in FIG. 3) is high enough to cause formation of the oxide layer 102 of the first metal.

After the oxide layer 102 is formed, a second metal layer (such as the second metal layer 104 of FIG. 1) may be deposited on the first metal layer 103. The second metal layer may include any metal element, compound or material that can conduct signals between the source/drain region 101 and circuits. For example, the second metal layer may include a W layer. In a particular embodiment, if the W layer contains fluorine (F), a TiN barrier layer may be formed between the W layer and the Ti layer.

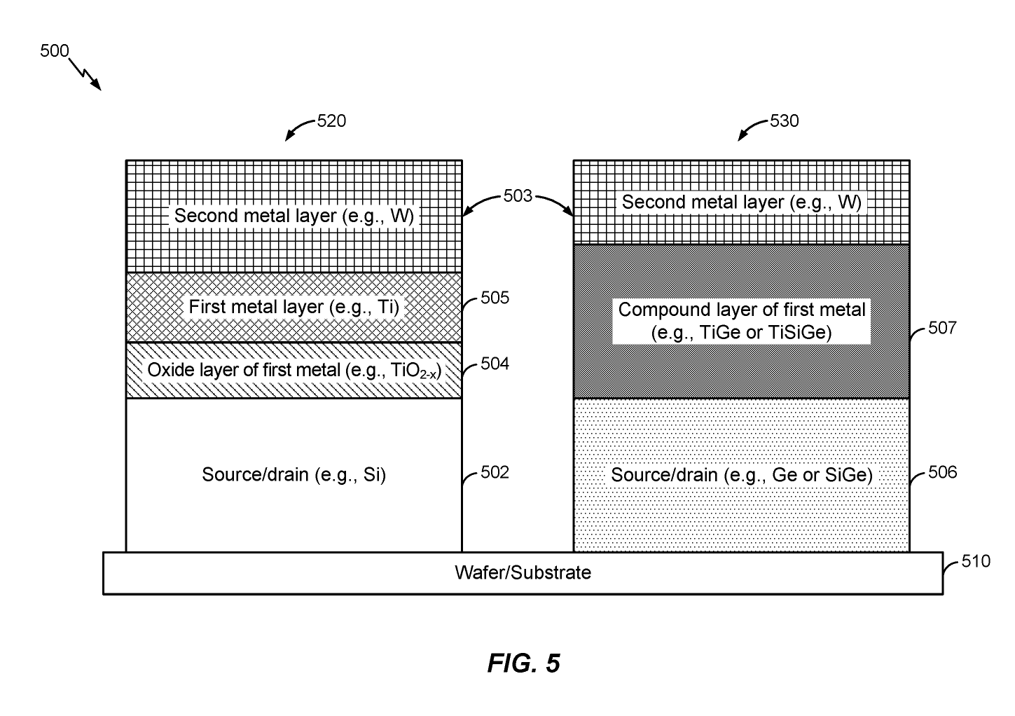

Referring to FIG. 5, a diagram of a particular embodiment of a device 500 that includes an NMOS device 520 with an MIS structure and a PMOS device 530 is shown. The device 500 may be considered a “dual contact” device, as the NMOS device 520 has a different contact type (e.g., an MIS structure) than the PMOS device 530. The NMOS device 520 and the PMOS device 530 may be formed on a common wafer or substrate 510 concurrently, without masking the NMOS device 520 during formation of the PMOS device 530, or vice versa, as further described herein.

The NMOS device 520 may include an MIS structure. For example, the NMOS device 520 may include a source/drain region 502, an oxide layer 504, a first metal layer 505, and a second metal layer 503. In an illustrative embodiment, the source/drain region 502 includes Si, the first metal layer 505 includes Ti, the oxide layer 504 includes TiO₂₋ₓ, and the second metal layer 503 includes W. It should be noted that the various materials described herein are for example only and not to be considered limiting. In alternate embodiments, other materials may be used to form n-type and PMOS devices.

The PMOS device 530 may include a source/drain region 506, a compound layer 507 of a first metal, and the second metal layer 503. For example, the second metal layer 503 may be common to the NMOS device 520 and the PMOS device 530. The source/drain region 506 may include one or more elements, compounds, or materials that enable a device to function as a PMOS device. For example, the source/drain region 506 may include Ge. As another example, the source/drain region 506 may include SiGe. Prior to depositing a layer on the source/drain region 506, the surface of the source/drain region 506 may be reacted to form an oxide layer. For example, the source/drain region 506 may be reacted with oxygen to form the oxide layer (not shown). The oxide layer may include a GeO₂ or SiGeO₂ layer. In a particular embodiment, the oxide layer may be removed prior to forming additional layers. For example, the oxide layer may be removed using a thermal treatment process. To illustrate, a GeO₂ or SiGeO₂ layer may decompose when the GeO₂ or SiGeO₂ layer is subjected to thermal treatment at a temperature of approximately 450° C.

The compound layer 507 may be formed by depositing the first metal layer 505 on the source/drain region 506. After depositing the first metal layer 505, an RTA process may be performed on the first metal layer 505. As a result of the RTA process, a portion of the first metal layer 505 that is disposed on the p-type source/drain region 506 may be transformed into the compound layer 507. The RTA process may also cause formation of the oxide layer 504 in the NMOS device 520. In an alternate embodiment, the RTA process may be skipped. For example, a temperature or energy level of the CVD or PVD process used to form the first metal layer 505 may be sufficient to cause formation of the oxide layer 504 and/or the compound layer 507. In some examples, the RTA process may be used to form a silicide (e.g., during formation of the PMOS device 530). In a particular embodiment, the source/drain region 506 includes Ge, the first metal layer includes Ti, and the compound layer 507 includes TiGe. In another particular embodiment, the source/drain region 506 includes SiGe, the first metal layer includes Ti, and the compound layer 507 includes TiSiGe.

The second metal layer 503 may be formed by depositing a second metal on the first metal layer 505 of the NMOS device 520 and the compound layer 507 of the PMOS device 530. The second metal layer 503 may include any metal element, compound, or material that is suitable for conducting signals between the source/drain regions 502, 506 and circuits. For example, the second metal layer 503 may include W. In a particular embodiment, a barrier layer, such as a titanium nitride (TiN) barrier layer, may be formed prior to forming the W layer if the W layer contains fluorine (F).

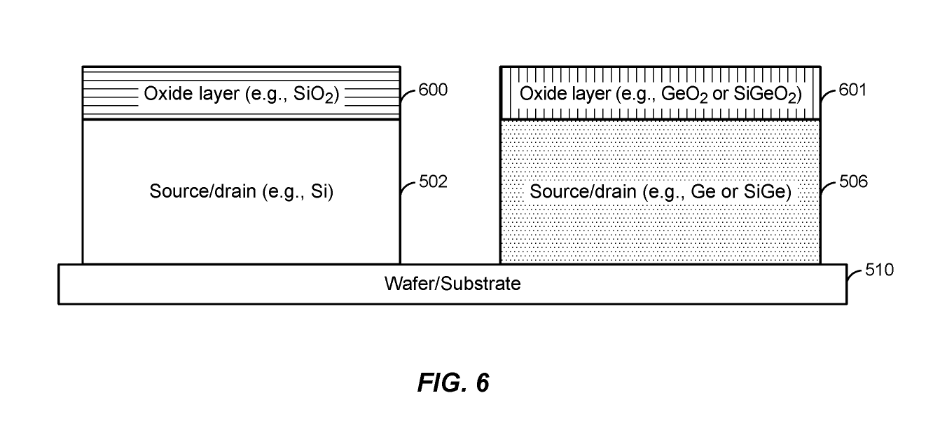

FIG. 5 thus illustrates a dual contact device 500 that includes different NMOS and PMOS structures. As further described with reference to FIGS. 6-9, the dual contact device 500 may be formed concurrently, without masking the NMOS device 520 during formation of the PMOS device 530, or vice versa. As a result, fabrication cost of the dual contact device 500 may be reduced.

FIGS. 6-9 illustrate stages of a process of manufacturing a dual contact device, such as the dual contact device 500 of FIG. 5. In FIG. 6, oxide surface layers 600 and 601 may be formed on the source/drain regions 502 and 506, respectively. For example, the source/drain regions 502 and 506 may be reacted in an oxygenated environment (e.g., with air) to form the oxide surface layers 600 and 601, respectively. The oxide surface layers 600 and 601 may be formed at the same time. When the source/drain region 502 includes Si, the oxide surface layer 600 may include SiO₂. When the source/drain region 506 includes Ge, the oxide surface layer 601 may include GeO₂. When the source/drain region 506 includes SiGe, the oxide surface layer 601 may include SiGeO₂. In alternate embodiments, the source/drain regions 502, 506 may include different materials and the oxide surface layers 600, 601 may include different oxides.

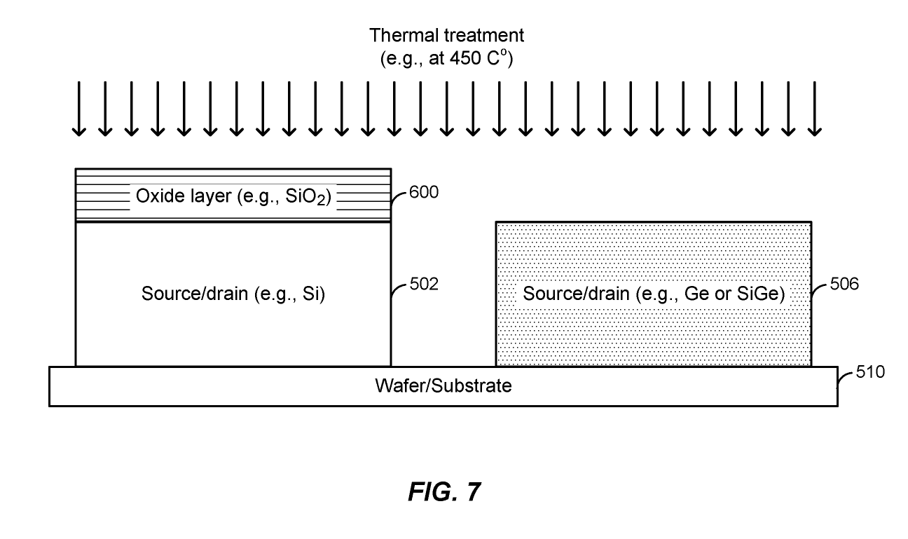

Referring to FIG. 7, a diagram of a particular embodiment of a second stage of forming a dual contact device is shown. The second stage may follow the first stage of FIG. 6. In FIG. 7, a thermal treatment may be applied to the dual contact device. As a result of the thermal treatment, the oxide layer 601 may be decomposed. However, the oxide layer 600 may not decompose. For example, the thermal treatment may correspond to a temperature of approximately 450 degrees Celsius (° C.). The oxide layer 601 (e.g., including GeO₂ or SiGeO₂) may decompose at 450° C. but the oxide layer 600 (e.g., including SiO₂) may be stable at 450° C.

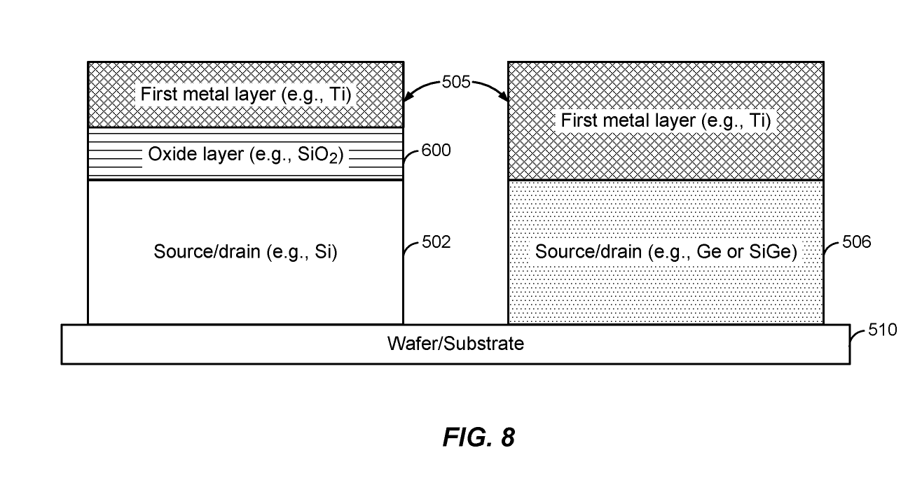

Referring to FIG. 8, a diagram of a particular embodiment of a third stage of forming a dual contact device is shown. The third stage may follow the second stage of FIG. 7. In FIG. 8, the first metal layer 505 may be deposited using a CVD or non-energetic PVD process. The first metal layer 505 may include any metal element, compound, or material that is capable of being deposited by the CVD or non-energetic PVD process, forming an oxide layer, and forming a compound layer. For example, the first metal layer 505 may include Ti.

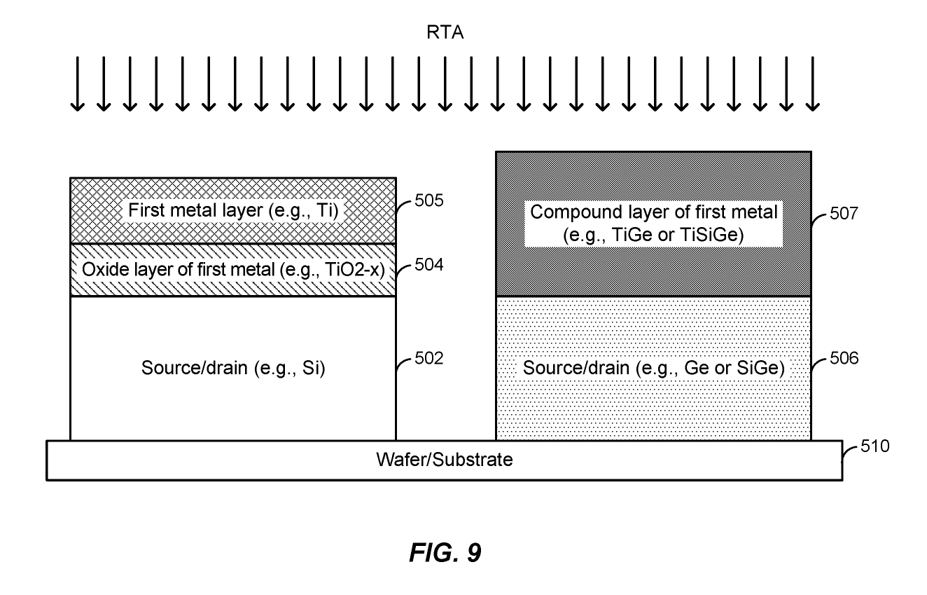

Referring to FIG. 9, a diagram of a particular embodiment of a fourth stage of forming a dual contact device is shown. The fourth stage may follow the third stage of FIG. 8. In FIG. 8, the first metal layer 505 may be heated using an RTA process. As a result of the RTA process, in the NMOS device, the first metal in the first metal layer 505 may react with oxygen in the oxide layer 600 and the oxide layer 504 may be formed between the first metal layer 505 and the source/drain region 502, as shown. For example, when the first metal layer 505 includes Ti, the oxide layer 504 may include TiO₂₋ₓ. A thickness of the oxide layer 504 may be related to a magnitude of contact resistance between the source/drain region 502 and the second metal layer 503. For example, when the oxide layer 504 is approximately 10 angstrom in thickness, the MIS structure shown on the left-hand side of FIGS. 5-9 may have a suitable contact resistance. In a particular embodiment, the thickness of the oxide layer 504 may be controlled by controlling a thickness of the oxide surface layer 600, a thickness of the first metal layer 505, a temperature of the RTA process, a duration of the RTA process, or a combination thereof.

In addition, as a result of the RTA process in the PMOS device, the first metal in the first metal layer 505 may react with the source/drain region 506, and the first metal layer 505 may be transformed into the compound layer 507. For example, when the source/drain region 506 includes Ge and the first metal layer 505 includes Ti, the compound layer 507 may include TiGe. As another example, when the source/drain region 506 includes SiGe and the first metal layer 505 includes Ti, the compound layer 507 may include TiSiGe. It should be noted that although FIG. 9 illustrates an RTA process, in alternate embodiments the RTA process may be skipped. For example, the RTA process may be skipped if prior manufacturing processes (e.g., CVD or PVD to form the first metal layer 505) have sufficient temperature/energy to cause formation of the oxide layer 504 and/or the compound layer 507.

After the oxide layer 504 and the compound layer 507 are formed, a second metal layer (such as the second metal layer 503 of FIG. 5) may be deposited on the first metal layer 505 in the NMOS device and on the compound layer 507 in the PMOS device. The second metal layer 503 may include any metal element, compound, or material that is capable of conducting signals between the source/drain regions 502 and 506 and circuits. For example, the second metal layer 503 may include W.

FIGS. 6-9 thus illustrate a process of fabricating a dual contact device 500 that includes an NMOS device with an MIS structure and a PMOS device having a different (e.g., non-MIS) structure. The process may form an MIS NMOS device and a PMOS device simultaneously and without masking one type of contact during formation of the other type of contact. As a result, a number of mask processes used during fabrication may be reduced, leading to a reduction in fabrication cost.

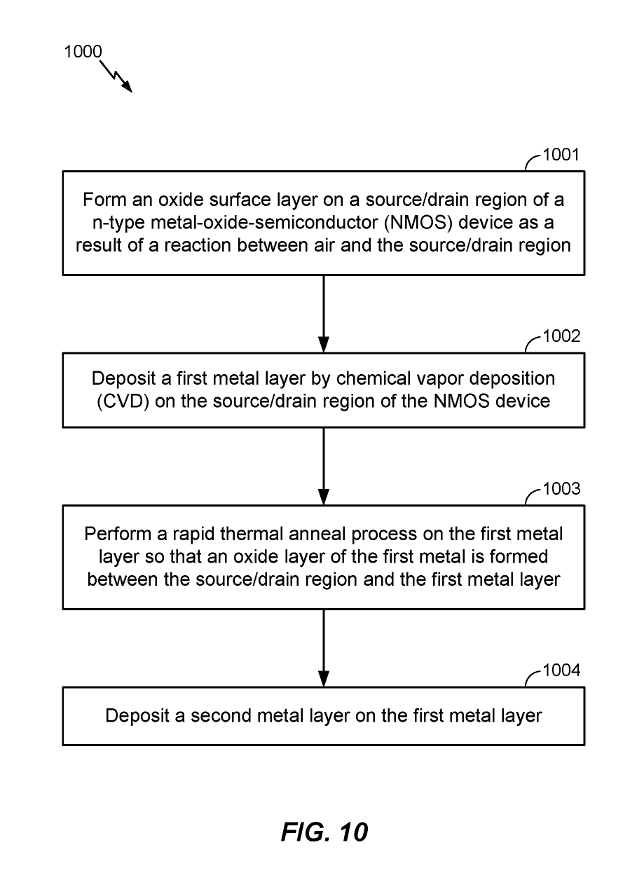

Referring to FIG. 10, a particular embodiment of a method of forming an MIS structure in an NMOS device is disclosed and generally designated 1000. The method may be illustrated with reference to FIGS. 1-4.

At 1001, an NMOS device may include a source/drain region (e.g., a Si source/drain region). For example, the source/drain region may be the source/drain region 101 of FIGS. 1-4. A surface of the source/drain region may be reacted to form an oxide layer (e.g., the oxide layer 200 of FIG. 2) on the surface of the source/drain region. For example, when the source/drain region includes Si, the oxide layer may include SiO₂.

At 1002, a first metal layer (e.g., the first metal layer 103 of FIG. 1) may be deposited using a CVD or non-energetic PVD process on the source/drain region. The first metal layer may include any metal element, compound, or material that is capable of being deposited using the CVD or non-energetic PVD process and is capable forming an oxide layer of the first metal. For example, the first metal may include Ti.

At 1003, an RTA process may be performed on the first metal layer. As a result of the RTA process, an oxide layer of the first metal (e.g., the oxide layer 102 of FIG. 1) may be formed between the source/drain region and the first metal layer. For example, when the source/drain region includes Si and the first metal layer includes Ti layer, the oxide layer of the first metal may include TiO₂₋ₓ. In a particular embodiment, the oxide layer is approximately 10 angstrom in thickness.

At 1004, a second metal layer (e.g., the second metal layer 104 of FIG. 1) may be formed by depositing a second metal on the first metal layer. The second metal layer may include any metal element, compound, or material that is suitable for conducting signals between the source/drain region and circuits. For example, the second metal layer may include W. FIG. 10 thus illustrates a method of forming a dual contact MIS structure of an NMOS device.

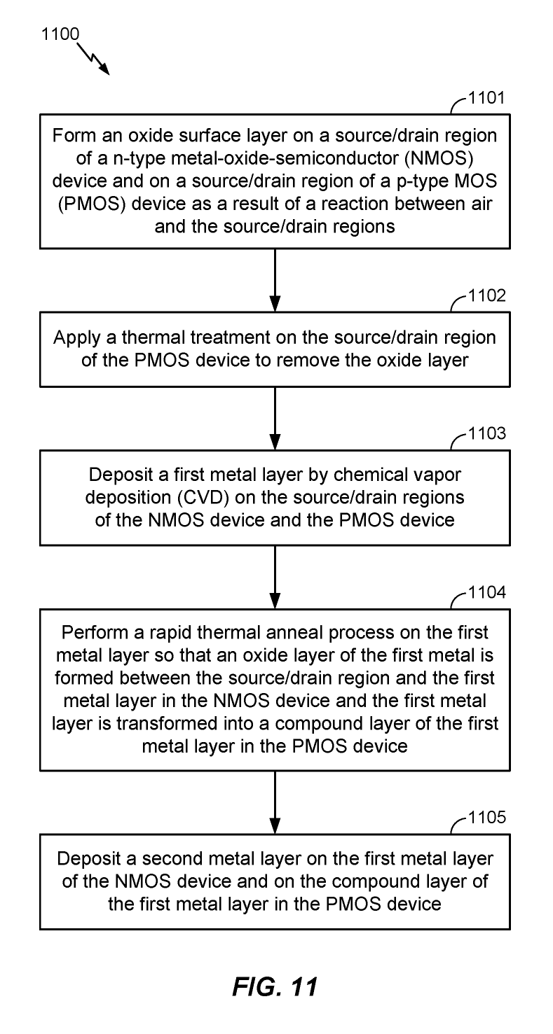

Referring to FIG. 11, a particular embodiment of a method of forming a dual contact device that includes an NMOS device with an MIS structure and a PMOS device is disclosed and generally designated 1100. The method may be illustrated with reference to FIGS. 5-9.

The dual contact device (e.g., the dual contact device 500 of FIG. 5) may include an NMOS device (e.g., the NMOS device 520) and a PMOS device (e.g., the PMOS device 530). The NMOS device may include a source/drain region (e.g., a source/drain region that includes Si). The source/drain region may be the source/drain region 502 of FIG. 5. Likewise, the PMOS device may include a source/drain region (e.g., a source/drain region that includes Ge or SiGe), such as the source/drain region 506 of FIG. 5. At 1101, surfaces of the n-type and p-type source/drain regions may be reacted to form oxide layers (e.g., the oxide layer 600 of FIG. 6 and the oxide layer 601 of FIG. 6) on the surfaces of the source/drain regions. For example, when the source/drain region of the NMOS device includes Si, an oxide layer including SiO₂ may be formed. When the source/drain region of the PMOS device includes Ge or SiGe, an oxide layer including GeO₂ layer or SiGeO₂ may be formed.

At 1102, a thermal treatment may be applied to the source/drain regions (e.g., the source/drain regions 502 and 506 of FIG. 5). The thermal treatment may correspond to a temperate (e.g., approximately 450° C.) at which the oxide layer 600 of FIG. 6 is stable and the oxide layer 601 of FIG. 6 is unstable. Thus, as a result of the thermal treatment, the oxide layer 601 of FIG. 6 may decompose.

At 1103, a first metal layer (e.g., the first metal layer 505 of FIG. 5) may be deposited on the source/drain regions (e.g., the source/drain regions 502 and 506 of FIG. 6) using a CVD or non-energetic PVD process. The first metal layer may include any metal element, compound, or material that is capable of being deposited by the CVD or non-energetic PVD process and forming an oxide layer of a first metal. For example, the first metal layer may include Ti.

At 1104, an RTA process may be performed on the first metal layer (e.g., the first metal layer 505 of FIG. 5). The RTA process may be performed at a temperature of between 300° C. and 800° C. As a result of the RTA process, in the NMOS device, the first metal in the first metal layer may react with oxygen in the oxide layer (e.g., the oxide layer 600 of FIG. 6) and an oxide layer of the first metal (e.g., the oxide layer 504 of FIG. 5) may be formed. For example, when the first metal layer includes Ti, the oxide layer of the first metal may include TiO₂₋ₓ. In a particular embodiment, the oxide layer of the first metal is approximately 10 angstrom in thickness. In addition, as a result of the RTA process, the first metal in the first metal layer of the PMOS device (e.g., the first metal layer 505 of FIG. 8) may react with the source/drain region (e.g., the source/drain region 506 of FIG. 5). The first metal layer may be transformed into a compound layer of the first metal (e.g., the compound layer 507 of FIG. 5). For example, when the source/drain region of the PMOS device includes Ge, the compound layer may include TiGe. As another example, when the source/drain region includes SiGe, the compound layer may include TiSiGe.

At 1105, a second metal layer may be deposited on the first metal layer of the NMOS device and on the compound layer of the PMOS device. The second metal layer may include any metal element, compound, or material that is suitable for conducting signals between the source/drain regions (e.g., the source/drain regions 502 and 506) and circuits. For example, the second metal layer may include W.

FIG. 11 thus illustrates a method of forming a dual contact device that includes an NMOS device having an MIS structure and a PMOS device. The dual contact device may have improved contact resistance between a source/drain region and a second metal layer (e.g., by controlling a thickness of an oxide layer in the MIS structure). The method may form contacts of the MIS structure device and the PMOS device simultaneously and without masking one type of contact during formation of the other type of contact. As a result, a number of mask processes used during fabrication may be reduced, leading to a reduction in fabrication cost of the dual contact device.

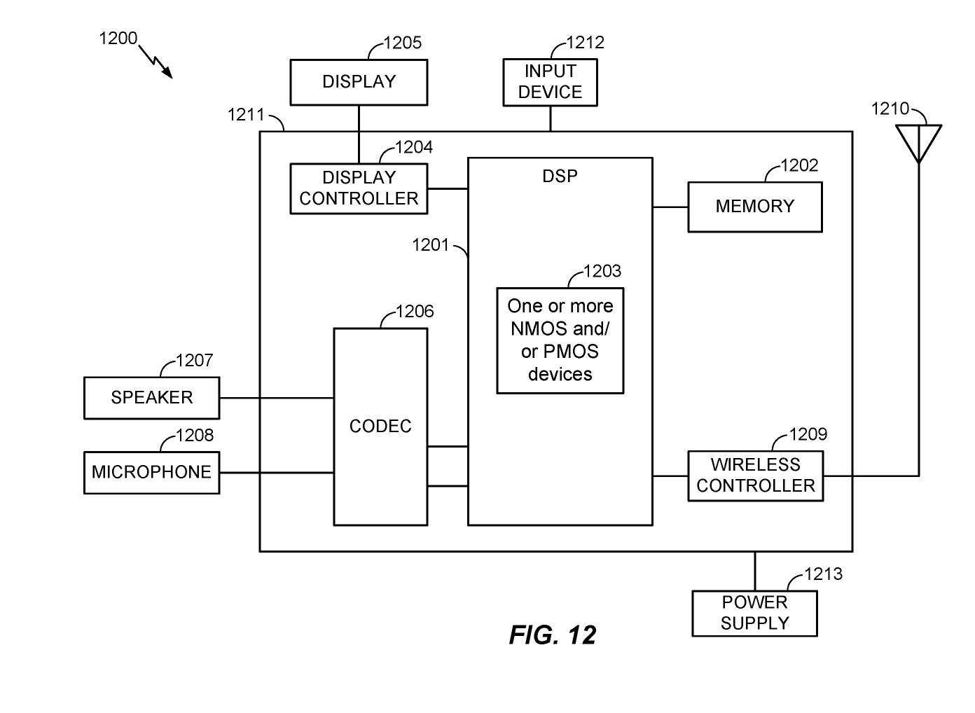

Referring to FIG. 12, a block diagram of a particular illustrative embodiment of a wireless communication device that includes an application of a dual contact MIS structure is disclosed and generally designated 1200. The device 1200 may be an electronic device, such as, an audio player, a video player, a navigation device, personal digital assistant (PDA), a communications device (e.g., a wireless telephone or smartphone), a portable computing device (e.g., a laptop computer, a tablet computer, a netbook computer, a smartbook computer, etc.), another type of device, or any combination thereof.

The device 1200 may include a processor 1201, such as a digital signal processor (DSP) or a central processing unit (CPU), coupled to a memory 1202. The processor 1201 may include one or more NMOS and/or PMOS devices 1203. In an illustrative embodiment, the one or more devices 1203 may correspond to the MIS structure 100 of FIG. 1 or the dual contact device 500 of FIG. 5.

In a particular embodiment, the one or more devices 1203 include an MIS structure. The MIS structure may include a source/drain region, an oxide layer of a first metal, a first metal layer, and a second metal layer. The first metal layer may be deposited using a CVD or non-energetic PVD process. The oxide layer of the first metal may be formed by performing an RTA process on the first metal layer. For example, the MIS structure may be fabricated as described with reference to FIGS. 1-4.

In a particular embodiment, the one or more devices 1203 include a dual contact device that includes an NMOS device and a PMOS device. The NMOS device may include an MIS structure. The PMOS device may include a different type of structure. For example, the PMOS device may include a source/drain region, a compound layer of a first metal, and a second metal layer. To illustrate, the dual contact device may be fabricated as described with reference to FIGS. 5-9.

FIG. 12 also shows a display controller 1204 that is coupled to the processor 1201 and to a display 1205. A coder/decoder (CODEC) 1206 can also be coupled to the processor 1201. A speaker 1207 and a microphone 1208 can be coupled to the CODEC 1206.

FIG. 12 also indicates that a wireless controller 1209 can be coupled to the processor 1201 and to an antenna 1210. In a particular embodiment, the processor 1201, the display controller 1204, the memory 1202, the CODEC 1206, and the wireless controller 1209 are included in a system-in-package or system-on-chip device 1211. In a particular embodiment, an input device 1212 and a power supply 1213 are coupled to the system-on-chip device 1211. Moreover, in a particular embodiment, as illustrated in FIG. 12, the display 1205, the input device 1212, the speaker 1207, the microphone 1208, the antenna 1210, and the power supply 1213 are external to the system-on-chip device 1211. However, each of the display 1205, the input device 1212, the speaker 1207, the microphone 1208, the antenna 1210, and the power supply 1213 can be coupled to a component of the system-on-chip device 1211, such as an interface or a controller.

In conjunction with the described embodiments, an apparatus may include means for sourcing current to a channel and for draining current from the channel. For example, the means for sourcing and for draining may include the source/drain region 101 of FIG. 1, the source/drain region 502 of FIG. 5, one or more other devices configured to source current to a channel and drain current from a channel, or any combination thereof. The apparatus may also include means for insulating. For example, the means for insulating may include the oxide layer 102 of FIG. 1, the oxide layer 504 of FIG. 5, one or more other devices configured to insulate, or any combination thereof. The apparatus may further include first means for conducting. For example, the first means for conducting may include the first metal layer 103 of FIG. 1, the first metal layer 505 of FIG. 5, one or more other devices configured to conduct, or any combination thereof. The apparatus may further include second means for conducting. For example, the second means for conducting may include the second metal layer 104 of FIG. 1, the second metal layer 503 of FIG. 5, one or more devices configured to conduct, or any combination thereof.

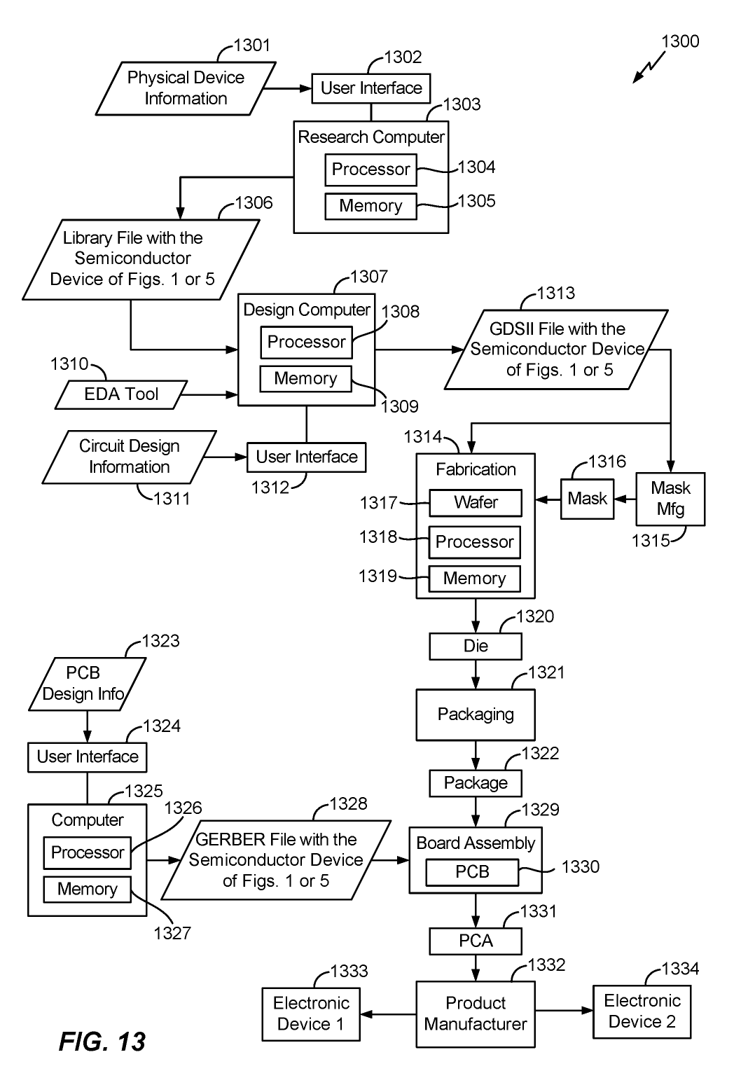

The foregoing disclosed devices and functionalities may be designed and configured into computer files (e.g. RTL, GDSII, GERBER, etc.) stored on computer-readable media. Some or all such files may be provided to fabrication handlers who fabricate devices based on such files. Resulting products include semiconductor wafers that are then cut into semiconductor die and packaged into a semiconductor chip. The chips are then employed in devices described above. FIG. 13 depicts a particular illustrative embodiment of a manufacturing process 1300 to fabricate a device including the MIS structure 100 of FIG. 1, the dual contact device 500 of FIG. 5, or both.

Physical device information 1301 is received at the manufacturing process 1300, such as at a research computer 1303. The physical device information 1301 may include design information representing at least one physical property of the MIS structure 100 of FIG. 1, the dual contact device 500 of FIG. 5, or a combination thereof. For example, the physical device information 1301 may include physical parameters, material characteristics, and structure information that is entered via a user interface 1302 coupled to the research computer 1303. The research computer 1303 includes a processor 1304, such as one or more processing cores, coupled to a computer-readable medium (e.g., a non-transitory computer-readable medium), such as a memory 1305. The memory 1305 may store computer-readable instructions that are executable to cause the processor 1304 to transform the physical device information 1301 to comply with a file format and to generate a library file 1306.

In a particular embodiment, the library file 1306 includes at least one data file including the transformed design information. For example, the library file 1306 may include a library of semiconductor devices including a device that includes the MIS structure 100 of FIG. 1, the dual contact device 500 of FIG. 5, or a combination thereof, that is provided for use with an electronic design automation (EDA) tool 1310.

The library file 1306 may be used in conjunction with the EDA tool 1310 at a design computer 1307 including a processor 1308, such as one or more processing cores, coupled to a memory 1309. The EDA tool 1310 may be stored as processor executable instructions at the memory 1309 to enable a user of the design computer 1307 to design a circuit including the MIS structure 100 of FIG. 1, the dual contact device 500 of FIG. 5, or a combination thereof, of the library file 1306. For example, a user of the design computer 1307 may enter circuit design information 1311 via a user interface 1312 coupled to the design computer 1307. The circuit design information 1311 may include design information representing at least one physical property of a semiconductor device, such as the MIS structure 100 of FIG. 1, the dual contact device 500 of FIG. 5, or a combination thereof. To illustrate, the circuit design property may include identification of particular circuits and relationships to other elements in a circuit design, positioning information, feature size information, interconnection information, or other information representing a physical property of a semiconductor device.

The design computer 1307 may be configured to transform the design information, including the circuit design information 1311, to comply with a file format. To illustrate, the file format may include a database binary file format representing planar geometric shapes, text labels, and other information about a circuit layout in a hierarchical format, such as a Graphic Data System (GDSII) file format. The design computer 1307 may be configured to generate a data file including the transformed design information, such as a GDSII file 1313 that includes information describing the MIS structure 100 of FIG. 1, the dual contact device 500 of FIG. 5, or a combination thereof, in addition to other circuits or information. To illustrate, the data file may include information corresponding to a system-on-chip (SOC) that includes the MIS structure 100 of FIG. 1, the dual contact device 500 of FIG. 5, or a combination thereof, and that also includes additional electronic circuits and components within the SOC.

The GDSII file 1313 may be received at a fabrication process 1314 to manufacture the MIS structure 100 of FIG. 1, the dual contact device 500 of FIG. 5, or a combination thereof, according to transformed information in the GDSII file 1313. For example, a device manufacture process may include providing the GDSII file 1313 to a mask manufacturer 1315 to create one or more masks, such as masks to be used with photolithography processing, illustrated as a representative mask 1316. The mask 1316 may be used during the fabrication process to generate one or more wafers 1317, which may be tested and separated into dies, such as a representative die 1320. The die 1320 includes a circuit including a device that includes the MIS structure 100 of FIG. 1, the dual contact device 500 of FIG. 5, or a combination thereof.

For example, the fabrication process 1314 may include a processor 1318 and a memory 1319 to initiate and/or control the fabrication process 1314. The memory 1319 may include executable instructions such as computer-readable instructions or processor-readable instructions. The executable instructions may include one or more instructions that are executable by a computer such as the processor 1318.

The fabrication process 1314 may be implemented by a fabrication system that is fully automated or partially automated. For example, the fabrication process 1314 may be automated according to a schedule. The fabrication system may include fabrication equipment (e.g., processing tools) to perform one or more operations to form a semiconductor device. For example, the fabrication equipment may be configured to deposit one or more materials, epitaxially grow one or more materials, conformally deposit one or more materials, apply a hardmask, apply an etching mask, perform etching, perform planarization, form a dummy gate stack, form a gate stack, perform a standard clean 1 type, perform thermal processes (e.g., rapid thermal anneal (RTA)), etc.

The fabrication system (e.g., an automated system that performs the fabrication process 1314) may have a distributed architecture (e.g., a hierarchy). For example, the fabrication system may include one or more processors, such as the processor 1318, one or more memories, such as the memory 1319, and/or controllers that are distributed according to the distributed architecture. The distributed architecture may include a high-level processor that controls or initiates operations of one or more low-level systems. For example, a high-level portion of the fabrication process 1314 may include one or more processors, such as the processor 1318, and the low-level systems may each include or may be controlled by one or more corresponding controllers. A particular controller of a particular low-level system may receive one or more instructions (e.g., commands) from a particular high-level system, may issue sub-commands to subordinate modules or process tools, and may communicate status data back to the particular high-level. Each of the one or more low-level systems may be associated with one or more corresponding pieces of fabrication equipment (e.g., processing tools). In a particular embodiment, the fabrication system may include multiple processors that are distributed in the fabrication system. For example, a controller of a low-level system component may include a processor, such as the processor 1318.

Alternatively, the processor 1318 may be a part of a high-level system, subsystem, or component of the fabrication system. In another embodiment, the processor 1318 includes distributed processing at various levels and components of a fabrication system.

Thus, the processor 1318 may include processor-executable instructions that, when executed by the processor 1318, cause the processor 1318 to initiate or control formation of a semiconductor device. For example, the semiconductor device may be semiconductor device of FIG. 1 or FIG. 5 and may be formed as illustrated with reference to FIGS. 2-4, FIGS. 6-9, the method of FIG. 10, the method of FIG. 11, or any combination thereof.

The executable instructions included in the memory 1319 may enable the processor 1318 to initiate formation of a semiconductor device, such as the MIS structure 100 of FIG. 1, the dual contact device 500 of FIG. 5, or a combination thereof. In a particular embodiment, the memory 1319 is a non-transient computer-readable medium storing computer-executable instructions that are executable by the processor 1318 to cause the processor 1318 to initiate formation of a semiconductor device, such as field-effect transistor (FET) or a metal-oxide-semiconductor (MOS) device, in accordance with at least a portion of any of the processes illustrated FIGS. 2-4 and 6-9, at least a portion of any of the methods of FIGS. 10-11, or any combination thereof. For example, the computer executable instructions may be executable to cause the processor 1318 to initiate formation of the semiconductor device. The semiconductor device may be formed by forming a first metal layer on source/drain regions of a device using a CVD or non-energetic PVD process and by performing an RTA process on the first metal layer after forming the first metal layer.

As an illustrative example, the processor 1318 may initiate or control a first step for forming a first metal layer on source/drain regions of a device using a CVD or non-energetic PVD process. For example, the processor 1318 may be embedded in or coupled to one or more controllers that control one or more pieces of fabrication equipment to perform the first step for forming a first metal layer on source/drain regions of a device using the CVD or non-energetic PVD process. The processor 1318 may control the first step for forming a first metal layer on source/drain regions of a device using the CVD or non-energetic PVD process by controlling one or more processes as described in the method 1000 of FIG. 10 at 1002 and the method 1100 of FIG. 11 at 1103.

The processor 1318 may also control a second step for performing an RTA process on the first metal layer after forming the first metal layer. For example, the processor 1318 may be embedded in or coupled to one or more controllers that control one or more pieces of fabrication equipment to perform the second step of performing an RTA process on the first metal layer after forming the first metal layer. The processor 1318 may control the second step for performing an RTA process on the first metal layer after forming the first metal layer by controlling one or more processes as described in the method 1000 of FIG. 10 at 1003 and the method 1100 of FIG. 11 at 1104.

The die 1320 may be provided to a packaging process 1321 where the die 1320 is incorporated into a representative package 1322. For example, the package 1322 may include the single die 1320 or multiple dies, such as a system-in-package (SiP) arrangement. The package 1322 may be configured to conform to one or more standards or specifications, such as Joint Electron Device Engineering Council (JEDEC) standards.

Information regarding the package 1322 may be distributed to various product designers, such as via a component library stored at a computer 1325. The computer 1325 may include a processor 1326, such as one or more processing cores, coupled to a memory 1327. A printed circuit board (PCB) tool may be stored as processor executable instructions at the memory 1327 to process PCB design information 1323 received from a user of the computer 1325 via a user interface 1324. The PCB design information 1323 may include physical positioning information of a packaged semiconductor device on a circuit board, the packaged semiconductor device corresponding to the package 1322 including the MIS structure 100 of FIG. 1, the dual contact device 500 of FIG. 5, or a combination thereof.

The computer 1325 may be configured to transform the PCB design information 1323 to generate a data file, such as a GERBER file 1328 with data that includes physical positioning information of a packaged semiconductor device on a circuit board, as well as layout of electrical connections such as traces and vias, where the packaged semiconductor device corresponds to the package 1322 including the MIS structure 100 of FIG. 1, the dual contact device 500 of FIG. 5, or a combination thereof. In other embodiments, the data file generated by the transformed PCB design information may have a format other than a GERBER format.

The GERBER file 1328 may be received at a board assembly process 1329 and used to create PCBs, such as a representative PCB 1330, manufactured in accordance with the design information stored within the GERBER file 1328. For example, the GERBER file 1328 may be uploaded to one or more machines to perform various steps of a PCB production process. The PCB 1330 may be populated with electronic components including the package 1322 to form a representative printed circuit assembly (PCA) 1331.

The PCA 1331 may be received at a product manufacture process 1332 and integrated into one or more electronic devices, such as a first representative electronic device 1333 and a second representative electronic device 1334. For example, the first representative electronic device 1333, the second representative electronic device 1334, or both, may include or correspond to the wireless communication device 1200 of FIG. 12. As an illustrative, non-limiting example, the first representative electronic device 1333, the second representative electronic device 1334, or both, may include a communications device, a fixed location data unit, a mobile location data unit, a mobile phone, a cellular phone, a satellite phone, a computer, a tablet, a portable computer, or a desktop computer. Alternatively or additionally, the first representative electronic device 1333, the second representative electronic device 1334, or both, may include a set top box, an entertainment unit, a navigation device, a personal digital assistant (PDA), a monitor, a computer monitor, a television, a tuner, a radio, a satellite radio, a music player, a digital music player, a portable music player, a video player, a digital video player, a digital video disc (DVD) player, a portable digital video player, any other device that stores or retrieves data or computer instructions, or a combination thereof, into which the MIS structure 100 of FIG. 1, the dual contact device 500 of FIG. 5, or a combination thereof, is integrated. As another illustrative, non-limiting example, one or more of the electronic devices 1333 and 1334 may include remote units, such as mobile phones, hand-held personal communication systems (PCS) units, portable data units such as personal data assistants, global positioning system (GPS) enabled devices, navigation devices, fixed location data units such as meter reading equipment, or any other device that stores or retrieves data or computer instructions, or any combination thereof. Although FIG. 13 illustrates remote units according to teachings of the disclosure, the disclosure is not limited to these illustrated units. Embodiments of the disclosure may be suitably employed in any device which includes active integrated circuitry including memory and on-chip circuitry.

A device that includes the MIS structure 100 of FIG. 1, the dual contact device 500 of FIG. 5, or a combination thereof, may be fabricated, processed, and incorporated into an electronic device, as described in the illustrative process 1300. One or more aspects of the embodiments disclosed with respect to FIGS. 1-12 may be included at various processing stages, such as within the library file 1306, the GDSII file 1313 (e.g., a file having a GDSII format), and the GERBER file 1328 (e.g., a file having a GERBER format), as well as stored at the memory 1305 of the research computer 1303, the memory 1309 of the design computer 1307, the memory 1327 of the computer 1325, the memory of one or more other computers or processors (not shown) used at the various stages, such as at the board assembly process 1329, and also incorporated into one or more other physical embodiments such as the mask 1316, the die 1320, the package 1322, the PCA 1331, other products such as prototype circuits or devices (not shown), or any combination thereof. Although various representative stages of production from a physical device design to a final product are depicted, in other embodiments fewer stages may be used or additional stages may be included. Similarly, the process 1300 may be performed by a single entity or by one or more entities performing various stages of the process 1300.

Although one or more of FIGS. 1-13 may illustrate systems, apparatuses, and/or methods according to the teachings of the disclosure, the disclosure is not limited to these illustrated systems, apparatuses, and/or methods. Embodiments of the disclosure may be suitably employed in any device that includes integrated circuitry including memory, a processor, and on-chip circuitry.

Although one or more of FIGS. 1-13 may illustrate systems, apparatuses, and/or methods according to the teachings of the disclosure, the disclosure is not limited to these illustrated systems, apparatuses, and/or methods. One or more functions or components of any of FIGS. 1-13 as illustrated or described herein may be combined with one or more other portions of another of FIGS. 1-13. Accordingly, no single embodiment described herein should be construed as limiting and embodiments of the disclosure may be suitably combined without departing form the teachings of the disclosure.

In conjunction with the described embodiments, a method includes forming a first metal layer on source/drain regions of a metal-oxide-semiconductor (MOS) device by chemical vapor deposition (CVD) or non-energetic physical vapor deposition (PVD). The method also includes selectively performing a rapid thermal anneal (RTA) process on the first metal layer after forming the first metal layer.

In another particular embodiment, an apparatus includes a processor and a memory storing instructions that, when executed by the processor, cause the processor to initiate forming a metal-insulator-semiconductor (MIS) structure. Forming the MIS structure includes forming a titanium layer on source/drain regions of an n-type metal-oxide-semiconductor (NMOS) device by CVD or non-energetic PVD. Forming the MIS structure also includes selectively performing an RTA process on the titanium layer to form a titanium oxide layer between the titanium layer and the source/drain regions.

In another particular embodiment, an apparatus includes means for applying a thermal treatment on source/drain regions of a p-type metal-oxide-semiconductor (PMOS) device to remove a silicon germanium or germanium oxide layer. For example, the means for applying the thermal treatment may include a fabrication system, a device corresponding to at least a portion of the fabrication process 1314 of FIG. 13, fabrication equipment configured to perform a thermal process, or any combination thereof. The apparatus also includes means for forming a titanium layer on the source/drain regions by CVD or non-energetic PVD. For example, the means for forming the titanium layer may include a fabrication system, a device corresponding to at least a portion of the fabrication process 1314 of FIG. 13, CVD or non-energetic PVD fabrication equipment, or any combination thereof. The apparatus further includes means for selectively performing an RTA process on the titanium layer to transform the titanium layer into a titanium silicon germanium layer. For example, the means for performing the RTA process may include a fabrication system, a device corresponding to at least a portion of the fabrication process 1314 of FIG. 13, fabrication equipment configured to perform RTA, or any combination thereof. The apparatus may further include means for forming a metal layer on the titanium silicon germanium layer. For example, the means for forming the metal layer on the titanium silicon germanium layer may include a fabrication system, a device corresponding to at least a portion of the fabrication process 1314 of FIG. 13, fabrication equipment configured to form a metal layer, or any combination thereof.

In another particular embodiment, a non-transitory computer-readable medium stores instructions that, when executed by a processor, cause the processor to initiate forming a dual contact structure. Forming the dual contact structure includes forming a first metal layer on source/drain regions of an NMOS device and on source/drain regions of a PMOS device by CVD or non-energetic PVD. Forming the dual contact structure also includes selectively performing an RTA process on the first metal layer after forming the first metal layer.

Those of skill would further appreciate that the various illustrative logical blocks, configurations, modules, circuits, and algorithm steps described in connection with the embodiments disclosed herein may be implemented as electronic hardware, computer software executed by a processor, or combinations of both. Various illustrative components, blocks, configurations, modules, circuits, and steps have been described above generally in terms of their functionality. Whether such functionality is implemented as hardware or processor executable instructions depends upon the particular application and design constraints imposed on the overall system. Skilled artisans may implement the described functionality in varying ways for each particular application, but such implementation decisions should not be interpreted as causing a departure from the scope of the present disclosure.

The steps of a method or algorithm described in connection with the embodiments disclosed herein may be embodied directly in hardware, in a software module executed by a processor, or in a combination of the two. A software module may reside in random access memory (RAM), flash memory, read-only memory (ROM), programmable read-only memory (PROM), erasable programmable read-only memory (EPROM), electrically erasable programmable read-only memory (EEPROM), registers, hard disk, a removable disk, a compact disc read-only memory (CD-ROM), or any other form of non-transient storage medium known in the art. An exemplary storage medium is coupled to the processor such that the processor can read information from, and write information to, the storage medium. In the alternative, the storage medium may be integral to the processor. The processor and the storage medium may reside in an application-specific integrated circuit (ASIC). The ASIC may reside in a computing device or a user terminal. In the alternative, the processor and the storage medium may reside as discrete components in a computing device or user terminal.

The previous description of the disclosed embodiments is provided to enable a person skilled in the art to make or use the disclosed embodiments. Various modifications to these embodiments will be readily apparent to those skilled in the art, and the principles defined herein may be applied to other embodiments without departing from the scope of the disclosure. Thus, the present disclosure is not intended to be limited to the embodiments shown herein but is to be accorded the widest scope possible consistent with the principles and novel features as defined by the following claims.

What is claimed is:

1. A method of forming a metal-insulator-semiconductor (MIS) structure, comprising:
forming a first metal layer on source/drain regions of a metal-oxide-semiconductor (MOS) device by chemical vapor deposition (CVD) or non-energetic physical vapor deposition (PVD); and
selectively performing a rapid thermal anneal (RTA) process on the first metal layer after forming the first metal layer.

2. The method of claim 1, wherein the source/drain regions comprise silicon, germanium, or a combination thereof.

3. The method of claim 1, wherein the first metal layer comprises a titanium layer.

4. The method of claim 3, wherein the MOS device comprises an n-type MOS (NMOS) device, wherein the RTA process is performed when a temperature or an energy of the CVD or non-energetic PVD is not sufficient to form a titanium oxide layer between the titanium layer and the source/drain regions, and wherein the RTA process causes formation of the titanium oxide layer between the titanium layer and the source/drain regions.

5. The method of claim 4, wherein the titanium oxide layer is approximately 10 angstrom in thickness.

6. The method of claim 4, further comprising forming a second metal layer on the titanium layer.

7. The method of claim 6, wherein the second metal layer comprises tungsten, and wherein a titanium nitride layer is formed between the second metal layer and the first metal layer when the second metal layer further comprises fluorine.

8. The method of claim 4, wherein, prior to forming the titanium layer, the source/drain regions have a silicon dioxide surface layer that is formed as a result of a reaction between oxygen and silicon in the source/drain regions.

9. The method of claim 3, wherein the MOS device comprises a p-type MOS (PMOS) device, and wherein the RTA process transforms the titanium layer into a titanium silicon germanium layer.

10. The method of claim 9, wherein, prior to forming the titanium layer, the source/drain regions have a silicon germanium or germanium oxide surface layer that is formed as a result of a reaction between oxygen and silicon germanium of the source/drain regions.

11. The method of claim 10, further comprising:
applying a thermal treatment to the source/drain regions to remove the silicon germanium or germanium oxide layer; and
forming a second metal layer on the titanium silicon germanium layer.

12. The method of claim 11, wherein the second metal layer comprises tungsten, and wherein a titanium nitride layer is formed between the second metal layer and the first metal layer when the second metal layer further comprises fluorine.

13. A method of forming a metal-insulator-semiconductor (MIS) structure, comprising:
forming a first oxide layer on first source/drain regions of an n-type metal-oxide-semiconductor (NMOS) device and a second oxide layer on second source/drain regions of a p-type MOS (PMOS) device;
applying a thermal treatment to remove the second oxide layer on the second source/drain regions but not the first oxide layer on the first source/drain regions;
forming a first metal layer by chemical vapor deposition (CVD) or non-energetic physical vapor deposition (PVD), the first metal layer including a first portion on the first oxide layer and a second portion on the second source/drain regions; and
selectively performing a rapid thermal anneal (RTA) process on the first metal layer after forming the first metal layer.

14. The method of claim 13, wherein the NMOS device and the PMOS device are formed on a common wafer or substrate.

15. The method of claim 14, wherein the NMOS device and the PMOS device are included in a dual contact device.

16. The method of claim 13, wherein the first oxide layer and the second oxide layer are formed substantially concurrently.

17. The method of claim 13, wherein the first oxide layer and the second oxide layer are formed by reacting an oxygenated environment or air with the first source/drain regions and the second source/drain regions.

18. The method of claim 13, wherein the thermal treatment is performed at approximately 450 degrees Celsius.

19. The method of claim 13, wherein performing the RTA process causes formation of a first metal oxide layer between the first portion of the first metal layer and the first source/drain regions of the NMOS device, and wherein performing the RTA process transforms the second portion of the first metal layer into a compound layer on the second source/drain regions of the PMOS device.

20. The method of claim 19, further comprising forming a second metal layer on the first portion of the first metal layer and on the compound layer.
